(19) United States
(12) Patent Application Publication
(10) Pub. No.: US 2010/0006906 A1
(43) Pub. Date: Jan. 14, 2010

(54) Semiconductor device, single crystalline silicon wafer, and single crystalline silicon ingot

(76) Inventors: Hwa-Sung Rhee, Seongnam-si (KR); Ho Lee, Cheonan-si (KR); Myung-Sun Kim, Hwaseong-si (KR); Ji-Hye Yi, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 12/458,500

(22) Filed: Jul. 14, 2009

(30) Foreign Application Priority Data
Jul. 14, 2008 (KR) 2008-68236

(51) Int. Cl. H01L 29/04

(52) U.S. Cl. 257/255; 257/628; 257/E29.004

(57) ABSTRACT

A semiconductor device includes a single crystalline substrate and an active region defined in the single crystalline substrate, wherein a major axis direction of the active region is aligned with a <0,1,1> family direction.

### BACKGROUND

1. Field

Embodiments relate to a semiconductor device, a single crystalline silicon wafer, and a single crystalline silicon ingot.

2. Description of the Related Art

A MOSFET device may include a gate oxide layer, a source, a drain, and an overlapping region. The overlapping region may be referred to as an extension region. A junction profile of the source and the drain may have an impact on a short channel effect. As the degree of integration of a device increases, the junction profile may be altered to form a shallow junction of the source and drain. A technique of an elevated source/drain (ESD) may be used in order to form the shallow junction of the source and the drain. The ESD technique may make a height of the source and the drain higher than a height of an active region.

### SUMMARY

Embodiments are directed to a semiconductor device, a single crystalline silicon wafer, and a single crystalline silicon ingot, which substantially overcome one or more problems due to the limitations and disadvantages of the related art.

It is therefore a feature of an embodiment to provide a semiconductor device having an active region disposed at an angle with respect to word and/or bit lines.

It is therefore another feature of an embodiment to provide a semiconductor device having elevated source/drain structures in combination with an angled active region.

It is therefore another feature of an embodiment to provide a single crystalline silicon ingot and a single crystalline silicon wafer suitable for forming a semiconductor device having an angled active region in combination with epitaxial elevated source/drain structures.

At least one of the above and other features and advantages may be realized by providing a semiconductor device, including a single crystalline silicon substrate, and an active region defined in the single crystalline silicon substrate. A major axis direction of the active region may be aligned with a <0,1,1> family direction.

The <0,1,1> family direction may include a <0,1,1> direction, a <0,−1,1> direction, a <0,−1,−1> direction, and a <0,1,−1> direction.

The major axis direction of the active region may be aligned parallel with the <0,1,−1> direction.

The major axis direction of the active region may be aligned parallel with the <0,1,1> direction.

The active region may include a source region and a drain region, the source and drain regions being disposed at opposite ends of the active region, a source epitaxial silicon layer may be on the source region, and a drain epitaxial silicon layer may be on the drain region.

The source epitaxial silicon layer and the drain epitaxial silicon layer may have the same crystalline orientation as the active region.

The source epitaxial silicon layer and the drain epitaxial silicon layer may be symmetrical with the active region.

The active region may include two source regions, the source regions being disposed at opposite ends of the active region, the active region may include a drain region disposed at a center of the active region, between the two source regions, a pair of word lines may be on the active region, the word lines diagonally crossing the active region, a bit line may be perpendicular to the word lines, a respective source epitaxial silicon layer may be on each source region, and a drain epitaxial silicon layer may be on the drain region.

The source epitaxial silicon layers and the drain epitaxial silicon layer may have the same crystalline orientation as the active region.

The source epitaxial silicon layers may be symmetrical with the active region.

The semiconductor device may further include a storage cell electrically connected to at least one of the source epitaxial silicon layers.

The active region may be defined by at least one isolation region bounding the active region.

At least one of the above and other features and advantages may also be realized by providing a single crystalline silicon ingot, including a crystalline direction marker offset in a clockwise direction, relative to a <0,1,1> direction, in a range of about 0° to about 45°.

The crystalline direction marker may be offset in the clockwise direction in a range of about 5° to about 40°.

At least one of the above and other features and advantages may also be realized by providing a single crystalline silicon ingot, including a crystalline direction marker offset in a clockwise direction, relative to a <0,−1,1> direction, in a range of about 0° to about 45°.

The crystalline direction marker may be offset in the clockwise direction in a range of about 5° to about 40°.

At least one of the above and other features and advantages may also be realized by providing a single crystalline silicon wafer, including a crystalline direction marker offset in a clockwise direction, relative to a <0,1,1> direction, in a range of about 0° to about 45°.

The crystalline direction marker may be offset in the clockwise direction in a range of about 5° to about 40°.

At least one of the above and other features and advantages may also be realized by providing a single crystalline silicon wafer, including a crystalline direction marker offset in a clockwise direction, relative to a <0,−1,1> direction, in a range of about 0° to about 45°.

The crystalline direction marker may be offset in the clockwise direction in a range of about 5° to about 40°.

### BRIEF DESCRIPTION OF THE DRAWINGS

The above and other features and advantages will become more apparent to those of ordinary skill in the art by describing in detail example embodiments with reference to the attached drawings, in which:

FIGS. 1A through 1C illustrate reference views of a single crystalline silicon wafer having a notch at a <0,1,1> direction;

FIGS. 2A through 2C illustrate views of a single crystalline silicon wafer according to a first embodiment;

FIGS. 3A through 3C illustrate views of a single crystalline silicon wafer according to a second embodiment;

FIG. 4 illustrates a view of an ingot according to a third embodiment;

FIGS. 5A and 5B illustrate top plan views of a semiconductor device according to a fourth embodiment; and

FIG. 6 illustrates a top plan view of a semiconductor device according to a fifth embodiment.

### DETAILED DESCRIPTION

Korean Patent Application No. 2008-68236, filed on Jul. 14, 2008, in the Korean Intellectual Property Office, and entitled: “Semiconductor Device, Single Crystalline Silicon Wafer and Single Crystalline Silicon Ingot,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc., may be used herein to describe various elements, these elements should not be limited by these terms. Rather, these terms are only used to distinguish one element from another. For example, a first region/layer could be termed a second region/layer and, similarly, a second region/layer could be termed a first region/layer without departing from the teachings of the disclosure.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” and “includes” and/or “including,” when used in this specification, specify the presence of stated features, regions, integers, steps, operations, elements, components, and/or groups thereof, but do not preclude the presence or addition of one or more other features, regions, integers, steps, operations, elements, components, and/or groups thereof.

Embodiments may be described with reference to cross-sectional illustrations that are schematic illustrations of idealized structures. As such, variations from the shapes of the illustrations, as a result, for example, of manufacturing techniques and/or tolerances, are to be expected. Thus, embodiments should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and/or the present application, and will not be interpreted in an idealized or overly formal sense unless expressly so defined herein.

Spatially relatively terms, such as “beneath,” “below,” “above,” “upper,” “top,” “bottom,” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned, elements described as below and/or beneath other elements or features would then be oriented (rotated 90 degrees or at other orientations) and the spatially relative descriptors used herein interpreted accordingly. As used herein, “height” refers to a direction that is generally orthogonal to the faces of a substrate.

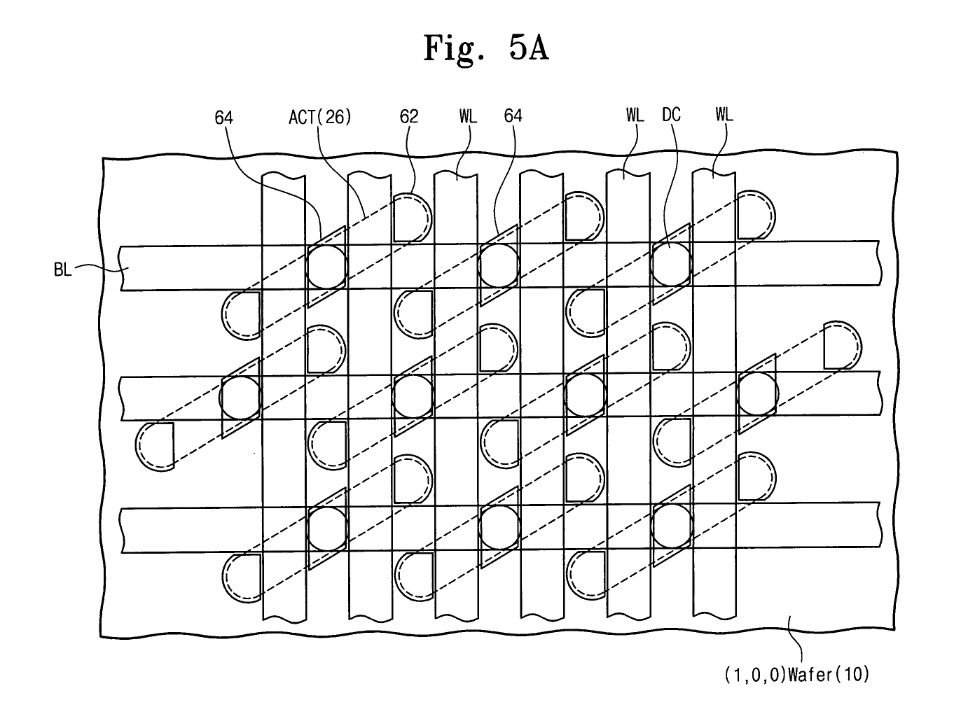

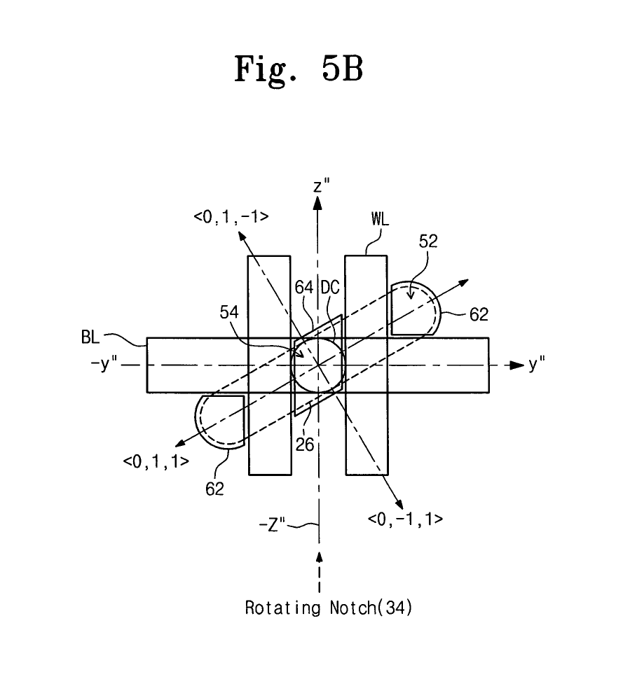

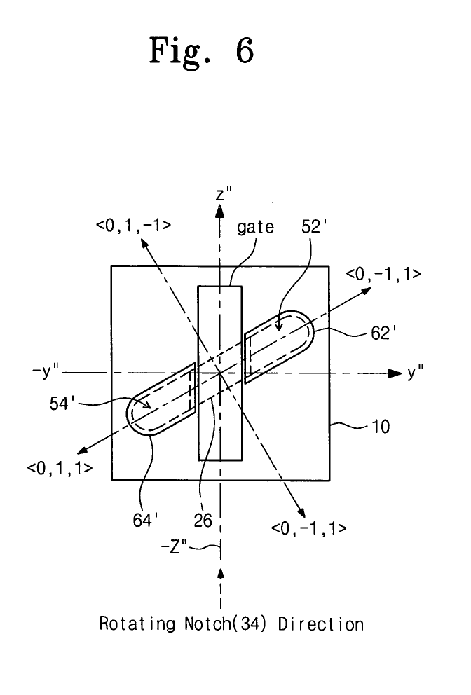

As the degree of integration of a semiconductor device increases, it may be desirable to form an active region at an angle with respect to word and/or bit lines, as shown in FIGS. 5A, 5B, and 6. Such a structure may help increase the packing density of structures in the semiconductor device, thereby enabling an increased degree of integration. Additionally, it may be desirable to form elevated source/drain (ESD) structures in combination with the angled active region, in order to provide a desired junction profile. Preferably, such ESD structures are formed using a process, e.g., an epitaxial process, that produces ESD structures having a single crystalline structure matched to the single crystalline structure of the corresponding underlying active region. That is, it is preferable that the ESD structures have a same crystalline structure as the corresponding source/drain regions in the active region. However, in a highly-integrated device, adjacent active regions should be isolated from one another. Therefore, it is preferable that the ESD formation process, e.g., epitaxy, should not create bridges between adjacent active regions.

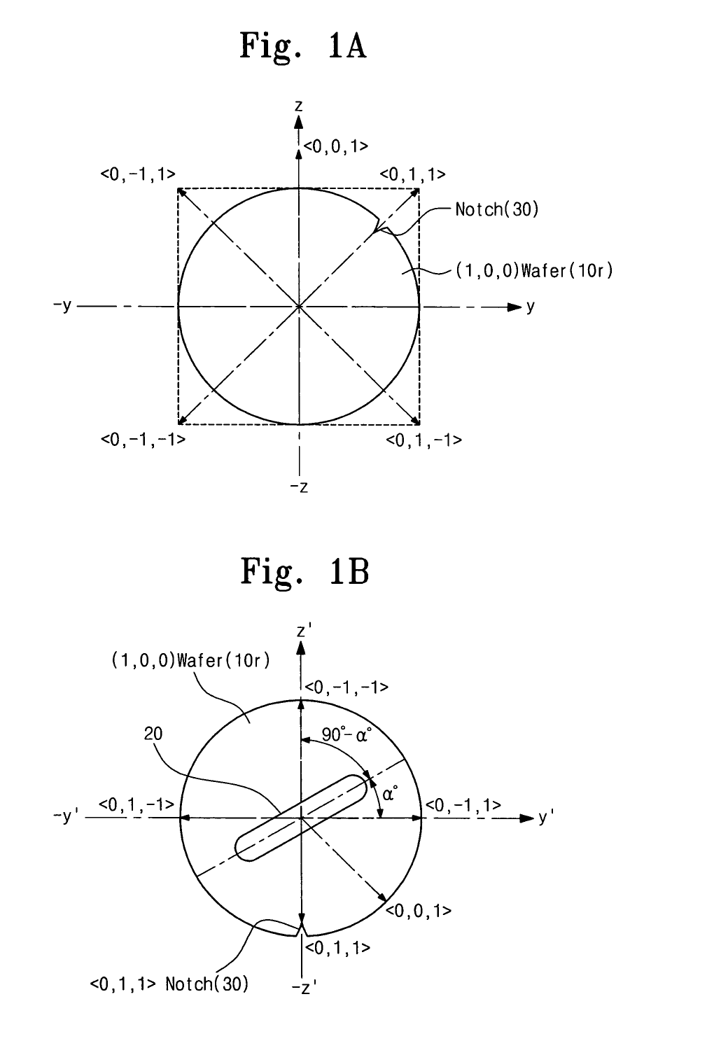

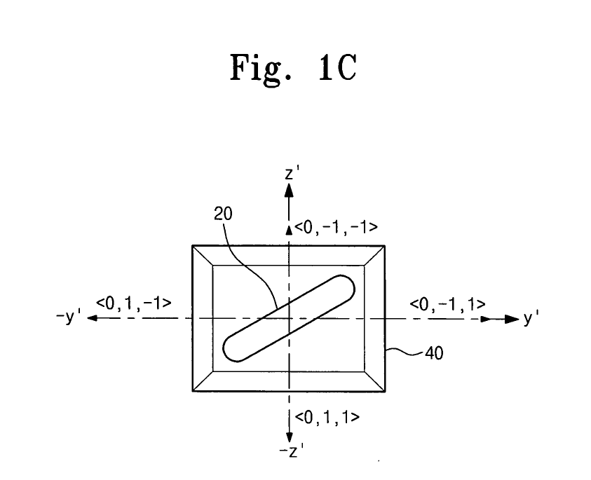

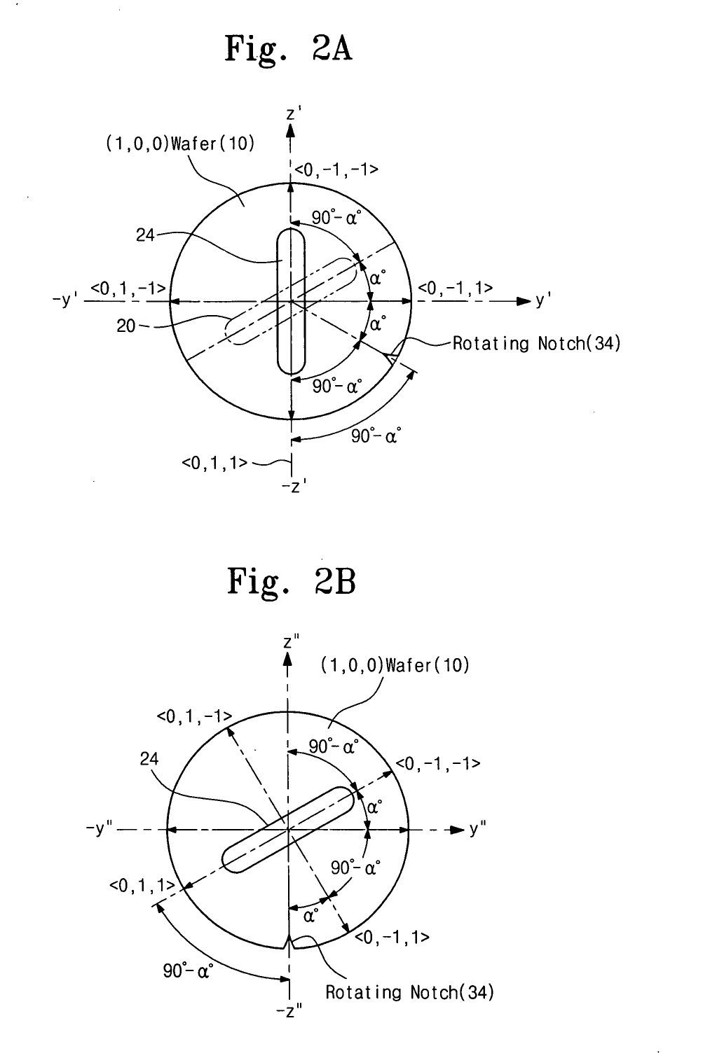

FIGS. 1A through 1C illustrate reference views of a single crystalline silicon wafer 30 having a notch 30 at a <0,1,1> direction. In further detail, FIG. 1A is a view representing directions of a (1,0,0) wafer 10r, in which the notch 30 is disposed to identify the <0,1,1> direction, and a z-axis is aligned with a <0,0,1> direction. FIG. 1B is a view illustrating an active region 20 oriented in a diagonal direction on the single crystalline silicon wafer 10r having the notch 30 at the <0,1,1> direction. In FIG. 1B, the single crystalline silicon wafer 10r is rotated such that the notch 30 is aligned with a z′-axis. FIG. 1C is a view illustrating a growth of an epitaxial silicon layer 40 on the active region 20 of FIG. 1B.

Referring to FIG. 1A, the surface of the single crystalline silicon wafer 10r illustrated in the drawing may be disposed on a (1,0,0) plane, where the (1,0,0) notation refers to Miller notation. A surface of the single crystalline silicon wafer 10r may have a <0,1,1> direction and a <0,1,−1> direction. The single crystalline silicon wafer 10r may include a crystalline direction marker to indicate a crystalline direction. The crystalline direction marker may be, or may include, a flat zone or the notch 30. For example, as shown in FIG. 1A, the notch 30 may be formed at the <0,1,1> direction. A wafer having the notch 30 formed at the <0,1,1> direction may be referred to as a “<1,1,0> standard wafer,” i.e., a <1,1,0> standard wafer includes a notch 30 at a <0,1,1> direction. A wafer having a notch formed at <0,0,1> direction (not shown) may be referred to as a “<1,0,0>45° tilted wafer.”

Referring to FIG. 1B, the single crystalline silicon wafer 10r is rotated in-plane with respect to FIG. 1A. To avoid confusion with the coordinate axes y and z in FIG. 1A, the coordinate axes in FIG. 1B are identified as the y′ and z′ axes.

Generally, a semiconductor process equipment such as a photolithography equipment performs a rotation alignment of the single crystalline silicon wafer 10r using the notch 30 as reference. The z′ axis and the y′ axis may be disposed to be a cross shape with respect to the notch 30. The notch 30 is disposed at an edge of the single crystalline silicon wafer 10r at the <0,1,1> direction. The active region 20 may be defined in the single crystalline silicon wafer 10r to form a semiconductor device. The active region 20 may be oriented in a diagonal direction, i.e., at an angle, relative to the z′ axis and the y′ axis. For example, as shown in FIG. 1B, the active region 20 may have a major axis that is rotated in a counter-clockwise direction by angle α′ with respect to the <0,−1,1> direction. The angle α between the y′ axis and the major axis of the active region 20 may depend on the particular design of the semiconductor device being fabricated. However, as shown in FIG. 1B, the major-axis direction of the active region 20 in a <0,1,1> standard wafer (or <1, 0, 0>45° tilted wafer) may not be parallel or antiparallel to the <0,1,1> direction or the <0,−1,1> direction. This may result in the formation of a broad epitaxial region, as described in detail below.

Referring to FIG. 1C, the epitaxial silicon layer 40 may be grown on the active region 20. The epitaxial silicon layer 40 may grow with a degree of directionality. In particular, the epitaxial silicon layer 40 may have a high growth rate in a <0,1,1> family direction. The <0,1,1> family direction includes the <0,1,1> direction, a <0,−1,1> direction, a <0,−1,−1> direction, and a <0,1,−1> direction. A direction of the major axis of the active region 20 and the <0,1,1> family direction may not located on the same straight line. Further, the epitaxial silicon layer 40 may grow on a wide area to minimize surface energy. Thus, the epitaxial silicon layer 40 that grows on the active region 20 may have a square shape in plan view and a truncated horn shape or trapezoid shape in profile view. Due to the large area of the epitaxial silicon layer 40, if active regions 20 are disposed to be adjacent to one another, the epitaxial silicon layers 40 may be shorted or bridged to one another.

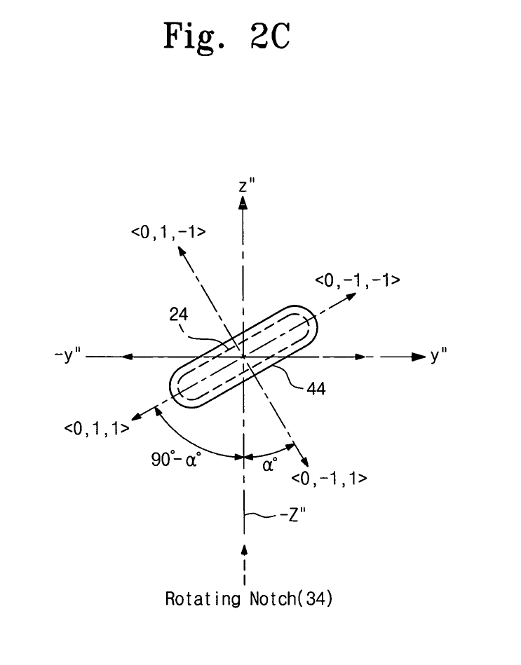

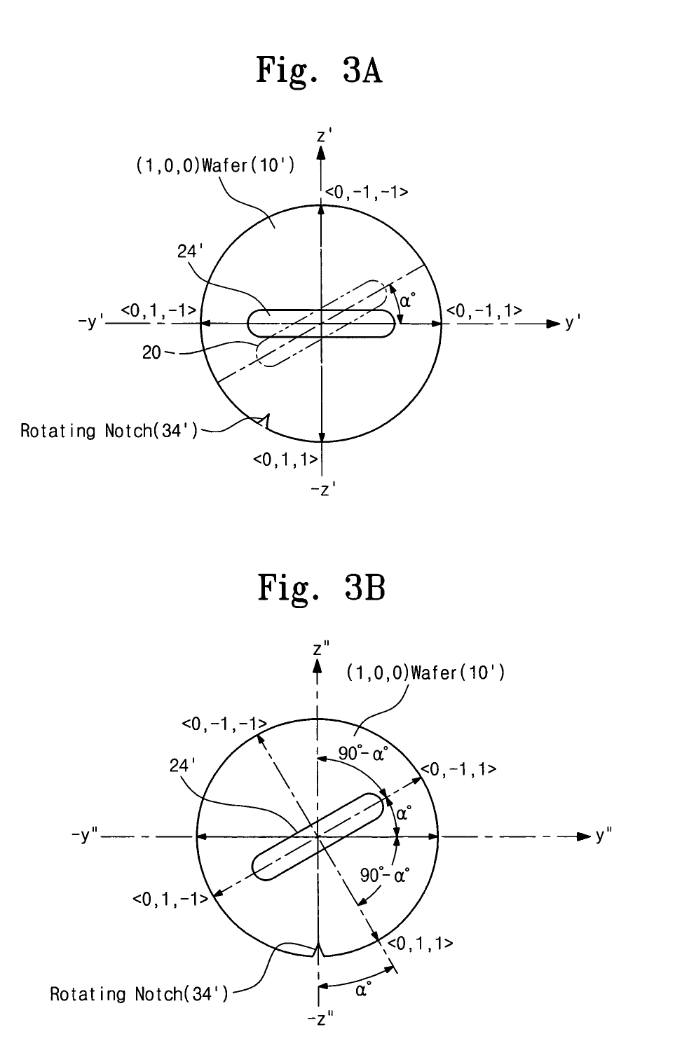

FIGS. 2A through 2C illustrate views of a single crystalline silicon wafer according to a first embodiment. In further detail, FIG. 2A shows a (1,0,0) plane single crystalline silicon wafer 10 oriented with the <0,1,1> direction aligned with the −z′ axis (as was the case for the wafer 10r in FIG. 1B) and having a rotating notch 34 offset in a counter-clockwise direction, relative to the notch 30 at the <0,1,1> direction of FIG. 1B, by an angle 90°-α°. FIG. 2B shows the wafer 10 of FIG. 2A rotated clockwise by the angle 90°-α° relative to FIG. 2A, such that the rotating notch 34 is at the bottom of the drawing. FIG. 2C is a view of an epitaxial silicon layer 44 grown on a rotated active region 24 of the wafer 10 of FIG. 2B.

Referring to FIG. 2A, the active region 20 of the <1,1,0> standard wafer 10r of reference FIG. 1B is represented as a dashed line for comparison purposes. As described above in connection with FIG. 1B, the active region 20 may have a major axis that is rotated in a counter-clockwise direction by the angle α° with respect to the <0,−1,1> direction. In contrast, as shown in FIG. 2A, the rotated active region 24 (solid line) has a major axis rotated in a counter-clockwise direction by the angle 90°-α° relative to the active region 20 shown in FIG. 1B, i.e., by 90° relative to the <0,−1,1> direction. Thus, the rotated active region 24 may have a major axis that is aligned parallel to the <0,1,1> direction.

Referring to FIG. 2B, the single crystalline silicon wafer 10 is rotated around the x axis (which extends out-of-plane) in a clockwise direction by the angle 90°-α° relative to FIG. 2A. Thus, the rotating notch 34 may be disposed at a lower portion of the single crystalline silicon wafer 10 and the rotated active region 24 may be disposed to have a major axis tilted by the angle α° with respect to a y″ axis. The rotated active region 24 may have the major axis aligned parallel with the <0,1,1> direction. The single crystalline silicon wafer 10 may be suitable for use in all the semiconductor process equipment of a <1,1,0> standard wafer, without alteration of the equipment. In contrast, if a major-axis direction of an active region on a <1,1,0> standard wafer is to be aligned in a <0,1,1> direction, photomask processes and measurement processes of all subsequent processes must be changed. Thus, use of the single crystalline silicon wafer 10 of the first embodiment may reduce process development time. The rotating notch 34 may be offset in a clockwise direction, relative to the <0,−1,1> direction, by an angle α that is in a range of about 0° to 45°. In an implementation, the angle α may be greater than 0° and less than 45°. For example, the angle α may be from about 5° to about 40°. Similarly, the rotating notch 34 may be offset in the clockwise direction, relative to the equivalent <0,1,−1> direction, by the angle α (not shown).

Referring to FIG. 2C, the epitaxial silicon layer 44 may be grown on the rotated active region 24 using, e.g., a SEG technique. The epitaxial silicon layer 44 can suppress an abnormal growth in a specified direction. In particular, since the major axis of the rotated active region 24 may be aligned in a <0,1,1> family direction, the epitaxial silicon layer 44 may be disposed to have an isotropy on the rotated active region 24, providing a shape symmetrical therewith.

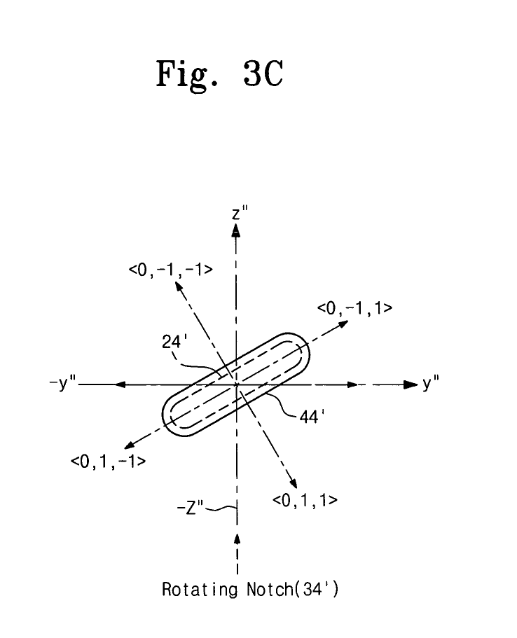

FIGS. 3A through 3C illustrate views of a single crystalline silicon wafer according to a second embodiment. In further detail, FIG. 3A illustrates a (1,0,0) plane single crystalline silicon wafer 10′ oriented with the <0,1,1> direction aligned with the −z′ axis (as was the case for the wafer 10r in FIG. 1B and the wafer 10 in FIG. 2A) and having a rotating notch 34′ offset in a clockwise direction by the angle α° relative to the <0,1,1> direction. FIG. 3B shows the wafer 10′ of FIG. 3A rotated counter-clockwise by the angle α° relative to FIG. 3A, such that the rotating notch 34′ is at the bottom of the drawing. FIG. 3C is a view of an epitaxial silicon layer 44′ grown on a rotated active region 24′ of the wafer 10′ of FIG. 3B.

Referring to FIG. 3A, the active region 20 of the <1,1,0> standard wafer 10r of reference FIG. 1B is again represented as a dashed line for comparison purposes. As described above in connection with FIG. 1B, the active region 20 may have a major axis that is rotated in a counter-clockwise direction by the angle α° with respect to the <0,−1,1> direction. In contrast, as shown in FIG. 3A, the rotated active region 10′ (solid line) is rotated in a clockwise direction by the angle α° relative to the active region 20 shown in FIG. 1B, i.e., to have a major axis aligned with the <0,−1,1> direction.

Referring to FIG. 3B, the single crystalline silicon wafer 10′ is rotated around the x axis (which extends out-of-plane) in a counter-clockwise direction by the angle α° relative to FIG. 3A. Thus, the rotating notch 34′ may be disposed at a lower portion of the single crystalline silicon wafer 10′ and the rotated active region 24′ may be disposed to have the major axis tilted by the angle α° with respect to a y″ axis. The rotated active region 24′ may have the major axis aligned parallel with the <0,−1,1> direction. The single crystalline silicon wafer 10 may be suitable for use in all the semiconductor process equipment of a <1,1,0> standard wafer, without alteration of the equipment. In contrast, if an active region on a <1,1,0> standard wafer is to be aligned in a <0,1,1> direction, photomask processes and measurement processes of all subsequent processes must be changed. Thus, the use of the single crystalline silicon wafer 10′ of the second embodiment may reduce process development time. The rotating notch 34′ may be offset in a clockwise direction, relative to the <0,1,1> direction, by an angle α that is in a range of about 0° to 45°. In an implementation, the angle α may be greater than 0° and less than 45°. For example, the angle α may be from about 5° to about 40°. Similarly, the rotating notch 34′ may be offset in the clockwise direction, relative to the equivalent <0,−1,−1> direction, by the angle α (not shown).

Referring to FIG. 3C, the epitaxial silicon layer 44′ may be grown on the rotated active region 24′ using, e.g., a SEG technique. The epitaxial silicon layer 44′ can suppress an abnormal growth on the rotated active region 24′. In particular, since a major axis of the rotated active region 24′ may be aligned in a <0,1,1> family direction, the epitaxial silicon layer 44′ may be disposed to have an isotropy on the rotated active region 24′ and may be symmetrical therewith.

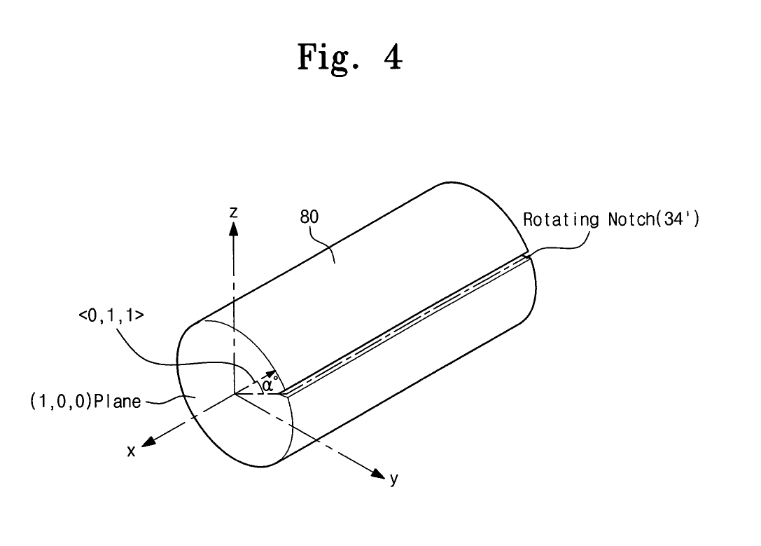

FIG. 4 illustrates a view of an ingot according to a third embodiment.

Referring to FIG. 4, a single crystal ingot 80 may be formed, e.g., using a melt formed from polysilicon, by a Czochralski (CZ) method. The ingot 80 may be formed in a quartz furnace by adding an impurity, e.g., of a 3 group element or a 5 group element to the melt. The polysilicon may be melted in the quartz furnace by heating, e.g., at a temperature of more than 1420° C. After the polysilicon and the impurity are liquefied, a single crystalline seed having a predetermined crystalline orientation may be placed in contact with a surface of the liquefied polysilicon. The quartz furnace and the single crystalline seed may be rotated in opposite directions to one another to obtain a uniform impurity distribution for the ingot 80. When the seed is lifted, the seed grows to form the ingot 80.

The CZ method may pull up the seed at a high speed at first to minimize a defect in the silicon single crystal. After that, the seed may be pulled up at a low speed to obtain a predetermined diameter. After the predetermined diameter is obtained, the seed may be pulled up at a set speed to maintain the diameter. As the seed is pulled up above the molten liquid, a surface tension may be generated between the seed and a surface of the molten liquid. As a result, shallow silicon layers may continuously cling to a surface of the seed while cooling. Thus, silicon in the molten liquid may solidify as a single crystal having the same crystalline orientation as the seed.

After the growth process is finished, the ingot 80 may have a diameter slightly greater than a diameter of the desired final product, and a surface grinding of the ingot 80 may be performed. At this time, a crystalline direction mark may be made in the ingot 80 to identify a particular crystalline direction in the single crystal. The crystalline direction marker may be the rotated notch 34 or 34′, or a corresponding flat zone, etc.

Referring to again to FIG. 3A, the crystalline direction marker may be the notch 34′ rotated in a clockwise direction by the angle α°, which may be, e.g., about 5° to about 40°, relative to the <0,1,1> direction. Cutting the ingot 80 parallel to a surface of the ingot 80 that is orthogonal to the formation axis, i.e., parallel to a surface in the y-z plane and orthogonal to the x axis, may be performed to form (1,0,0) plane wafers. The notch 34′ may be formed on an exterior of the ingot 80 so that the major direction of an active region of a semiconductor device and a <0,1,1> family direction are located on a same straight line when the device is formed on a resulting wafer. In another embodiment, referring to FIG. 2B, the crystalline direction marker (notch 34) may be rotated in a clockwise direction by the angle α°, e.g., about 5° to about 40°, relative to the <0,−1,1> direction, and may be formed on an exterior of the ingot 80 so that an active region of a semiconductor device and a <0,1,1> family direction are located on a same straight line (not shown in FIG. 4).

A single crystalline silicon wafer may be formed by cutting the ingot. When a SEG process is performed using the resultant single crystalline silicon wafer, the active region and a <0,1,1> family direction may be located on a same straight line, which may suppress an abnormal growth on the side of an epitaxial silicon layer growing on the active region such that the shape of the epitaxial silicon layer closely corresponds to the shape of the active region. Accordingly, when the active regions are densely disposed, e.g., in the case of a highly-integrated device, the formation of undesirable bridges between adjacent active regions may be prevented.

A wafer formed by cutting the ingot 80 may go through an edge grinding process to grind a circumference of the wafer to a round shape. The edge grinding process may reduce breakage the wafer during subsequent wafer production processes and device manufacturing processes. Also, an edge polishing process may be performed. The edge polishing process may help maintain purity and may reduce breakage by as much as 400%. Also, a lapping process may be performed. The lapping process may remove saw marks and defects from the front and back surfaces of the wafer, and may also grind down the thickness of the wafer to an optimum thickness. The lapping process may also remove internal stresses generated during the cutting process. Also, an etching may be performed. The etching process may use a mixed etchant including, e.g., hydrochloric acid, nitric acid, and/or acetic acid, to remove minute splits and defects generated during the lapping process. Also, a polishing process may be performed. The polishing process may be performed in a production line having a high cleanliness so as to maintain purity. A wafer of a prime grade may go through polishing processes of two to three steps using a fine abrasive or slurry. A front side polishing process may be applied to wafers. For 300 mm wafers, both sides may be subjected to an abrasive process. A specular surface may be formed on the wafer on which the polishing process is performed. A semiconductor device may be formed on the specular surface during a semiconductor device manufacturing process. Also, a cleaning process may be performed. The cleaning process may remove particles, metal contaminants, residues, etc., remaining on the wafer surface. Also, a backside scrubbing process may be performed to remove small particles.

FIGS. 5A and 5B illustrate top plan views of a semiconductor device according to a fourth embodiment. In further detail, FIG. 5B is an enlarged view of a vicinity of an active region (ACT) 26 of FIG. 5A.

Referring to FIGS. 5A and 5B, the active region 26 may be formed on a single crystalline silicon wafer 10 (or 10′; for convenience, the following description will discuss the wafer 10. However, it will be understood that the wafer 10′ may be similarly used). A major axis direction of the active region 26 may be aligned with a <0,1,1> family direction. Source regions 52 may be disposed at opposite ends of the major axis direction of the active region 26. A drain region 54 may be disposed at a center of the active region 26. A pair of word lines (WL) may be disposed on each active region 26 and may diagonally cross the active region 26. A bit line (BL) may be provided to be perpendicular to the pair of word lines (WL). A respective source epitaxial silicon layer 62 may be on each source region 52 and a drain epitaxial silicon layer 64 may be on the drain region 54. The drain epitaxial silicon layer 64 may be electrically connected to the bit line (BL). The source epitaxial silicon layers 62 and the drain epitaxial silicon layer 64 may have the same crystalline orientation as the underlying active region 26. The drain epitaxial silicon layer 64 may be disposed between the pair of word lines (WL). The source epitaxial silicon layers 62 may grow to have an isotropy on the source regions 52. The drain epitaxial silicon layer 64 may grow to have an isotropy on the drain region 54. The source epitaxial silicon layers 62 may be electrically connected to memory cells (not shown). The memory cells may be, e.g., electric capacitors or other storage memory cells. During formation of the device, a direction of the rotating notch 34 may be parallel or antiparallel to the z″ axis.

As discussed above, the major axis direction of the active region 26 may be aligned with a <0,1,1> family direction. Thus, the active regions 26 may be diagonally disposed and may be disposed to be adjacent to each other. For an area 6F2 of a unit memory cell having a minimum line width (F), each active region 26 may diagonally extend with respect to a proceeding direction of a word line (WL). The active regions 26 may be disposed by a 6F2 design rule. A tilting angle α° of the active region 26 may be in the range of, e.g., about 5° to about 40° with respect to the bit line direction. The rotating notch 34 may be rotated in a clockwise direction by the tilting angle of α°, relative to the <0,−1,1> direction.

The active regions 26 may be disposed at regular intervals in the y″ axis direction to form a first row, a second row, and a third row. In an implementation, the first, second, and third rows may each be aligned in the z″ axis direction (not shown). In another implementation, the second row may be disposed to be offset from the first and third rows, as shown in FIG. 5A. A space between adjacent active regions 26 may be filled with a device isolation layer such as an insulator, e.g., oxide, etc., (not shown).

The pair of word lines (WL) may be disposed on the active region 26. The word lines may be aligned in the z″ axis direction. The word lines may divide the active region 26 into the source regions 52 and the drain region 54. The source epitaxial silicon layers 62 may be disposed on the source regions 52. The drain epitaxial silicon layer 64 may be disposed on the drain region 54. The source epitaxial silicon layers 62 and the drain epitaxial silicon layer 64 may be formed by, e.g., a SEG technique. Since the active region 26 may be aligned in a <0,1,1> family direction, the source epitaxial silicon layers 62 and the drain epitaxial silicon layer 64 may have an isotropy and may grow along a shape of the active region 26. Accordingly, the source epitaxial silicon layers 62 may not be bridged to adjacent source epitaxial silicon layers 62 and the drain epitaxial silicon layers 64 may not be bridged to adjacent drain epitaxial silicon layers 64. The bit line and the drain epitaxial silicon layer 64 may be electrically connected to each other through a bit line contact plug (DC).

In another implementation, an active region under the word lines (WL) may be recessed. As a result, a length of a channel may be increased.

FIG. 6 illustrates a top plan view of a semiconductor device according to a fifth embodiment.

Referring to FIG. 6, the active region 26 is formed on a single crystalline silicon wafer 10 (or 10′) and a major direction of the active region 26 may be aligned in a <0,1,1> family direction. A gate may be disposed to cross the active region 26. The active region 26 may include a source region 52′ and a drain region 54′ disposed at opposite ends of the active region 26. A source epitaxial silicon layer 62′ may be disposed on the source region 52′. A drain epitaxial silicon layer 64′ may be disposed on the drain region 54′. The source epitaxial silicon layer 62′ and the drain epitaxial silicon layer 64′ may have the same crystalline orientation as the active region 26. The source epitaxial silicon layer 62′ and the drain epitaxial silicon layer 64′ may be formed by, e.g., a SEG technique. The source epitaxial silicon layer 62′ and the drain epitaxial silicon layer 64′ may grow to be symmetrical with, i.e., isotropic to, the active region.

As described above, embodiments may provide a semiconductor device having a high degree of integration. An active region may be disposed at an angle with respect to word and/or bit lines, such that the packing density of structures in the semiconductor device is high, thereby enabling an increased degree of integration. Additionally, embodiments may provide a semiconductor device having ESD structures in combination with the angled active region. The formation of such ESD structures may be simplified by providing for epitaxial growth in a predetermined direction, such that adjacent active regions are isolated from one another and bridging between adjacent active regions is reduced or eliminated. Further, an ingot, and a wafer made from the same, may be formed with a crystalline direction marker, e.g., a primary flat, a notch, etc., in a predetermined location, such that a semiconductor device having an active region angled at a predetermined angle may be fabricated without the need for extensive alteration of semiconductor process equipment used during the fabrication.

Example embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A semiconductor device, comprising:
a single crystalline silicon substrate; and
an active region defined in the single crystalline silicon substrate, wherein a major axis direction of the active region is aligned with a <0,1,1> family direction.

2. The semiconductor device as claimed in claim 1, wherein the <0,1,1> family direction includes a <0,1,1> direction, a <0,−1,1> direction, a <0,−1,−1> direction, and a <0,1,−1> direction.

3. The semiconductor device as claimed in claim 2, wherein the major axis direction of the active region is aligned parallel with the <0,1,−1> direction.

4. The semiconductor device as claimed in claim 2, wherein the major axis direction of the active region is aligned parallel with the <0,1,1> direction.

5. The semiconductor device as claimed in claim 1, wherein:
the active region includes a source region and a drain region, the source and drain regions being disposed at opposite ends of the active region,
a source epitaxial silicon layer is on the source region, and
a drain epitaxial silicon layer is on the drain region.

6. The semiconductor device as claimed in claim 5, wherein the source epitaxial silicon layer and the drain epitaxial silicon layer have the same crystalline orientation as the active region.

7. The semiconductor device as claimed in claim 5, wherein the source epitaxial silicon layer and the drain epitaxial silicon layer are symmetrical with the active region.

8. The semiconductor device as claimed in claim 1, wherein:
the active region includes two source regions, the source regions being disposed at opposite ends of the active region,
the active region includes a drain region disposed at a center of the active region, between the two source regions,
a pair of word lines is on the active region, the word lines diagonally crossing the active region,
a bit line is perpendicular to the word lines,
a respective source epitaxial silicon layer is on each source region, and
a drain epitaxial silicon layer is on the drain region.

9. The semiconductor device as claimed in claim 8, wherein the source epitaxial silicon layers and the drain epitaxial silicon layer have the same crystalline orientation as the active region.

10. The semiconductor device as claimed in claim 8, wherein the source epitaxial silicon layers are symmetrical with the active region.

11. The semiconductor device as claimed in claim 8, further comprising a storage cell electrically connected to at least one of the source epitaxial silicon layers.

12. The semiconductor device as claimed in claim 1, wherein the active region is defined by at least one isolation region bounding the active region.

13. A single crystalline silicon ingot, comprising:
a crystalline direction marker offset in a clockwise direction, relative to a <0,1,1> direction, in a range of about 0° to about 45°.

14. The single crystalline silicon ingot as claimed in claim 13, wherein the crystalline direction marker is offset in the clockwise direction in a range of about 5° to about 40°.

15. A single crystalline silicon ingot, comprising:
a crystalline direction marker offset in a clockwise direction, relative to a <0,−1,1> direction, in a range of about 0° to about 45°.

16. The single crystalline silicon ingot as claimed in claim 15, wherein the crystalline direction marker is offset in the clockwise direction in a range of about 5° to about 40°.

17. A single crystalline silicon wafer, comprising:
a crystalline direction marker offset in a clockwise direction, relative to a <0,1,1> direction, in a range of about 0° to about 45°.

18. The single crystalline silicon wafer as claimed in claim 17, wherein the crystalline direction marker is offset in the clockwise direction in a range of about 5° to about 40°.

19. A single crystalline silicon wafer, comprising:
a crystalline direction marker offset in a clockwise direction, relative to a <0,−1,1> direction, in a range of about 0° to about 45°.

20. The single crystalline silicon wafer as claimed in claim 19, wherein the crystalline direction marker is offset in the clockwise direction in a range of about 5° to about 40°.
